(19) United States
(12) Patent Application Publication
(10) Pub. No.: US 2024/0088193 A1
(43) Pub. Date: Mar. 14, 2024

(54) SEMICONDUCTOR DEVICE AND METHOD FOR MANUFACTURING THE SAME

(71) Applicant: TAIWAN SEMICONDUCTOR MANUFACTURING COMPANY LTD., HSINCHU (TW)

(72) Inventors: CHUN-LIANG LU, TAINAN CITY (TW); CHUN-HAO CHOU, TAINAN CITY (TW); KUO-CHENG LEE, TAINAN CITY (TW)

(21) Appl. No.: 18/154,017

(22) Filed: Jan. 12, 2023

Related U.S. Application Data
(60) Provisional application No. 63/375,052, filed on Sep. 8, 2022.

(51) Int. Cl. H01L 27/146

(52) U.S. Cl. CPC H01L 27/14645; H01L 27/14689

(57) ABSTRACT

A semiconductor device and a method for manufacturing the semiconductor device are provided. The semiconductor device comprises a substrate and a wafer disposed on the substrate. The wafer includes a p-doped layer disposed on the substrate; a first diode disposed on the p-doped layer; a second diode disposed on the p-doped layer; a third diode disposed on the p-doped layer; and a dielectric layer disposed on the substrate and covering the first, second, and third diodes. The first, second, and third diodes are disposed side by side.

### PRIORITY CLAIM AND CROSS-REFERENCE

This application claims the benefit of prior-filed provisional application No. 63/375,052, filed on 8 Sep. 2022.

### BACKGROUND

Traditional CMOS image sensors use color filters for respective illumination optics to utilize photodiode absorption. However, the structure of the CMOS image sensor with color filters has a large thickness. Thus, a thinner image sensor is needed.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 is a cross-sectional view of a semiconductor device, in accordance with some embodiments of the present disclosure.

FIG. 2A is a cross-sectional view of a semiconductor substrate, in accordance with some embodiments of the present disclosure.

FIG. 2B is a cross-sectional view of a semiconductor substrate, in accordance with some embodiments of the present disclosure.

FIG. 3A is a cross-sectional view of a semiconductor substrate applied with different voltages, in accordance with some embodiments of the present disclosure.

FIG. 3B is a cross-sectional view of a semiconductor substrate applied with different voltages, in accordance with some embodiments of the present disclosure.

FIG. 4A is a top view of patterns of PIN diodes of a semiconductor device, in accordance with some embodiments of the present disclosure.

FIG. 4B is a top view of patterns of PIN diodes of a semiconductor device, in accordance with some embodiments of the present disclosure.

FIG. 4C is a top view of patterns of PIN diodes of a semiconductor device, in accordance with some embodiments of the present disclosure.

FIG. 5A to FIG. 5P illustrates a method of manufacturing a semiconductor device according to some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

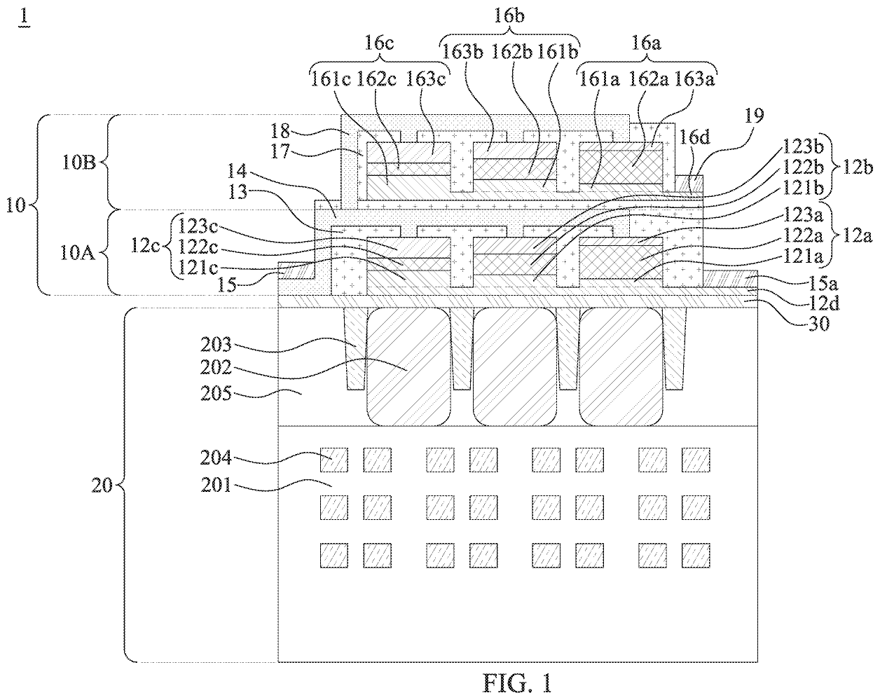

FIG. 1 is a cross-sectional view of a semiconductor device 1 in accordance with some embodiments of the present disclosure. The semiconductor device 1 may be a CMOS image sensor. The semiconductor device 1 includes a first substrate 10 and a second substrate 20. The first substrate 10 may be a semiconductor device. The first substrate 10 may be also referred to as “a wafer”, “a second wafer” or “an assembly structure”. The second substrate 20 may be a semiconductor device. The second substrate 20 may be also referred to as “a substrate”, “a first wafer” or “a base structure”. The first substrate 10 is disposed on the second substrate 20. A passivation layer 30 is sandwiched between the first substrate 10 and the second substrate 20. A material of the passivation layer 30 may include, silicon oxide (SiO₂), silicon nitride (Si₃N₄), silicon oxynitride (N₂OSi₂), silicon nitride oxide (N₂OSi₂), etc. The passivation layer 30 is used for planarization for the second substrate 20, such that the first substrate 10 would be easily and smoothly formed on the second substrate 20. In some embodiments, the first substrate 10 may be a semiconductor wafer. The second substrate 20 may be a semiconductor wafer. Light may be incident from outside (e.g., the top side of the first substrate 10) through the first substrate 10 and enter the second substrate 20. The light may be ambient light.

The second substrate 20 includes a substrate region 201, a photodiode 202, an isolation structure 203, a metal layer 204, and a doped region 205. The second substrate 20 may be a semiconductor substrate (e.g., a wafer). The second substrate 20 may be a silicon substrate.

Alternatively, in other embodiments, the second substrate 20 may further include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP, or combinations thereof. In other embodiments, the second substrate 20 may include, for example, an insulating layer such as a SiO₂ or a Si₃N₄ layer in addition to a semiconductor substrate portion. Thus, the term second substrate 20 may also include silicon-on-glass, and silicon-on-sapphire substrates. Also, the second substrate 20 may be any other base on which a layer is formed, for example a glass or metal layer. Accordingly, the second substrate 20 may be a wafer such as a blanket wafer or may be a layer applied to another base material, e.g., an epitaxial layer grown onto a lower layer.

The substrate region 201 may be a silicon carrier. The material of the substrate region 201 may include intrinsic silicon (Si).

The metal layer 204 is disposed or embedded within the substrate region 201. The metal layer 204 may be a circuit layer and may be connected to other components. There can be many metal-oxide-semiconductor field-effect transistors (MOSFETs) in the substrate region 201 (not shown here). The metal layer 204 may be connected to the MOSFETs.

The doped region 205 is disposed on the substrate region 201. The doped region 205 may be a p-doped silicon region. The photodiode 202 and the isolation structure 203 are disposed within the doped region 205. In some embodiments, the isolation structure 203 may be a shallow trench isolation (STI) structure. The STI structure may include, for example, silicon oxide (SiO₂), silicon nitride (Si₃N₄), silicon oxynitride (N₂OSi₂), silicon nitride oxide (N₂OSi₂), etc. The STI structure may reduce the optical or electrical cross-talk between the neighboring photodiodes 202.

Two adjacent isolation structures 203 may define an active region. The photodiode 202 may be surrounded by the isolation structures 203. The photodiode 202 may extend from the passivation layer 30 to the substrate region 201. A depth of the photodiode 202 is greater than a depth of the isolation structure 203. The photodiode 202 has a light exposure area adjacent to the passivation layer 30. The photodiode 202 stores photogenerated charges.

The first substrate 10 includes a lower structure 10A and an upper structure 10B on the lower structure 10A. The lower structure 10A includes a plurality of PIN diodes 12a, 12b, 12c, a p-doped layer 12d, a first dielectric layer 13, a first conductive layer 14, and a plurality of conductive pads 15, 15a. The upper structure 10B includes a plurality of PIN diodes 16a, 16b, 16c, a p-doped layer 16d, a second dielectric layer 17, a second conductive layer 18, and a conductive pad 19.

The p-doped layer 12d is disposed on the passivation layer 30 and partially covered by the first dielectric layer 13. The p-doped layer 12d extends in the first dielectric layer 13 and protrudes from the first dielectric layer 13. One conductive pad 15a is disposed on a protrusion of the p-doped layer 12d. The conductive pad 15a may be functioned as an anode. That is, the conductive pad 15a may be configured to be an anode.

The PIN diodes 12a, 12b, 12c are disposed on and connected to the p-doped layer 12d. The PIN diodes 12a, 12b, 12c are disposed in parallel or disposed side by side. The PIN diodes 12a, 12b, 12c are covered by the first dielectric layer 13. The PIN diodes 12a, 12b, 12c may include a first lower PIN diode 12a, a second lower PIN diode 12b and a third lower PIN diode 12c. A size (including a length, a width, and a thickness) of the first lower PIN diode 12a is substantially the same as a size of the second lower PIN diode 12b. The size of the first lower PIN diode 12a is substantially the same as a size of the third lower PIN diode 12c.

The first lower PIN diode 12a includes a p-doped Si layer 121a, an intrinsic Si layer 122a, and an n-doped Si layer 123a. The p-doped Si layer 121a is disposed on the p-doped layer 12d. The intrinsic Si layer 122a is disposed on the p-doped Si layer 121a. The n-doped Si layer 123a is disposed on the intrinsic Si layer 122a. The p-doped Si layer 121a and the p-doped layer 12d are integrally formed. In some embodiments, the p-doped Si layer 121a and the p-doped layer 12d may be formed as one layer.

The second lower PIN diode 12b includes a p-doped Si layer 121b, an intrinsic Si layer 122b, and an n-doped Si layer 123b. The p-doped Si layer 121b is disposed on the p-doped layer 12d. The intrinsic Si layer 122b is disposed on the p-doped Si layer 121b. The n-doped Si layer 123b is disposed on the intrinsic Si layer 122b. The p-doped Si layer 121b and the p-doped layer 12d are integrally formed. In some embodiments, the p-doped Si layer 121b and the p-doped layer 12d may be formed as one layer.

The third lower PIN diode 12c includes a p-doped Si layer 121c, an intrinsic Si layer 122c, and an n-doped Si layer 123c. The p-doped Si layer 121c is disposed on the p-doped layer 12d. The intrinsic Si layer 122c is disposed on the p-doped Si layer 121b. The n-doped Si layer 123c is disposed on the intrinsic Si layer 122b. The p-doped Si layer 121c and the p-doped layer 12d are integrally formed. In some embodiments, the p-doped Si layer 121c and the p-doped layer 12d may be formed as one layer.

In some embodiments, the p-doped Si layer 121a, the p-doped Si layer 121b, the p-doped Si layer 121c, and the p-doped layer 12d are integrally formed. The p-doped Si layer 121a, the p-doped Si layer 121b, the p-doped Si layer 121c, and the p-doped layer 12d may be formed as one layer.

The first conductive layer 14 is disposed in the first dielectric layer 13. The first conductive layer 14 is electrically connected to the PIN diodes 12a, 12b, 12c. The first conductive layer 14 is electrically in contact with the n-doped Si layer 123a of the first lower PIN diode 12a, the n-doped Si layer 123b of the second lower PIN diode 12b, and the n-doped Si layer 123c of the third lower PIN diode 12c. The first dielectric layer 13 partially covers the p-doped layer 12d. A portion of the first conductive layer 14 extends vertically alone a lateral surface of the first dielectric layer 13. The first conductive layer 14 includes a protrusion which protrudes from the lateral surface of the first dielectric layer 13. One conductive pad 15 is disposed on the protrusion of the first conductive layer 14. The conductive pad 15 may be functioned as a cathode. That is, the conductive pad 15 may be configured to be a cathode. A power may be supplied to the PIN diodes 12a, 12b, 12c from the conductive pads 15.

The first conductive layer 14 may be a transparent conductive layer. In some embodiments, a material of the first conductive layer 14 may include an indium-containing or gallium-containing metal oxide semiconductor material (e.g., indium-gallium-zinc oxide (IGZO), indium-zinc oxide (IZO), indium-tin oxide (ITO) or indium tungsten oxide (IWO)), a zinc-containing metal oxide semiconductor material (e.g., zinc oxide (ZnO), gallium-zinc oxide (GZO), zinc-tin oxide (ZTO) or combinations thereof).

The p-doped layer 16d is partially covered by the second dielectric layer 17. The p-doped layer 16d extends in the second dielectric layer 17 and protrudes from the second dielectric layer 17. The conductive pad 19 is disposed on a protrusion of the p-doped layer 16d. The conductive pad 19 may be functioned as an anode. That is, the conductive pad 19 may be configured to be an anode.

The PIN diodes 16a, 16b, 16c are disposed on and connected to the p-doped layer 16d. The PIN diodes 16a, 16b, 16c are disposed in parallel or side by side. The PIN diodes 16a, 16b, 16c are covered by the second dielectric layer 17. The PIN diodes 16a, 16b, 16c may include a first upper PIN diode 16a, a second upper PIN diode 16b and a third upper PIN diode 16c. A size of the first upper PIN diode 16a is substantially the same as a size of the second upper PIN diode 16b. The size of the first upper PIN diode 16a is substantially the same as a size of the third upper PIN diode 16c.

The first upper PIN diode 16a includes a p-doped Si layer 161a, an intrinsic Si layer 162a, and an n-doped Si layer 163a. The p-doped Si layer 161a is disposed on the p-doped layer 16d. The intrinsic Si layer 162a is disposed on the p-doped Si layer 161a. The n-doped Si layer 163a is disposed on the intrinsic Si layer 162a. The p-doped Si layer 161a and the p-doped layer 16d are integrally formed. In some embodiments, the p-doped Si layer 161a and the p-doped layer 16d may be formed as one layer.

The second upper PIN diode 16b includes a p-doped Si layer 161b, an intrinsic Si layer 162b, and an n-doped Si layer 163b. The p-doped Si layer 161b is disposed on the p-doped layer 16d. The intrinsic Si layer 162b is disposed on the p-doped Si layer 161b. The n-doped Si layer 163b is disposed on the intrinsic Si layer 162b. The p-doped Si layer 161b and the p-doped layer 16d are integrally formed. In some embodiments, the p-doped Si layer 161b and the p-doped layer 16d may be formed as one layer.

The third upper PIN diode 16c comprises a p-doped Si layer 161c, an intrinsic Si layer 162c, and an n-doped Si layer 163c. The p-doped Si layer 161c is disposed on the p-doped layer 16d. The intrinsic Si layer 162c is disposed on the p-doped Si layer 161b. The n-doped Si layer 163c is disposed on the intrinsic Si layer 162b. The p-doped Si layer 161c and the p-doped layer 16d are integrally formed. In some embodiments, the p-doped Si layer 161c and the p-doped layer 16d may be formed as one layer.

In some embodiments, the p-doped Si layer 161a, the p-doped Si layer 161b, the p-doped Si layer 161c, and the p-doped layer 16d are integrally formed. The p-doped Si layer 161a, the p-doped Si layer 161b, the p-doped Si layer 161c, and the p-doped layer 16d may be formed as one layer.

The second conductive layer 18 is disposed on the second dielectric layer 17. The second conductive layer 18 is electrically connected to the PIN diodes 16a, 16b, 16c. The second conductive layer 18 is electrically in contact with the n-doped Si layer 163a of the first upper PIN diode 16a, the n-doped Si layer 163b of the second upper PIN diode 16b, and the n-doped Si layer 163c of the third upper PIN diode 16c. The second dielectric layer 17 partially covers the p-doped layer 16d. A portion of the second conductive layer 18 extends vertically alone a lateral surface of the second dielectric layer 17. The second conductive layer 18 is electrically connected to the first conductive layer 14. A power may be supplied to the PIN diodes 16a, 16b, 16c from the conductive pads 15 and 19.

The second conductive layer 18 may be a transparent conductive layer. In some embodiments, a material of the second conductive layer 18 may include an indium-containing or gallium-containing metal oxide semiconductor material (e.g., indium-gallium-zinc oxide (IGZO), indium-zinc oxide (IZO), indium-tin oxide (ITO) or indium tungsten oxide (IWO)), a zinc-containing metal oxide semiconductor material (e.g., zinc oxide (ZnO), gallium-zinc oxide (GZO), zinc-tin oxide (ZTO) or combinations thereof). In some embodiments, the material of the second conductive layer 18 may be the same as the material of the first conductive layer 14. The material of the second conductive layer 18 may be different from the material of the first conductive layer 14.

The first lower PIN diode 12a is located directly under the first upper PIN diode 16a. One photodiode 202 is located directly under the first lower PIN diode 12a for receiving or absorbing light passing through the first lower PIN diode 12a and the first upper PIN diode 16a. The second lower PIN diode 12b is located directly under the second upper PIN diode 16b. One photodiode 202 is located directly under the second lower PIN diode 12b for receiving or absorbing light passing through the second lower PIN diode 12b and the second upper PIN diode 16b. The third lower PIN diode 12c is located directly under the third upper PIN diode 16c. One photodiode 202 is located directly under the third lower PIN diode 12c for receiving or absorbing light passing through the third lower PIN diode 12c and the third upper PIN diode 16c.

In some embodiment, the photodiode 202 located directly under the first lower PIN diode 12a and the first upper PIN diode 16a may receive or absorb blue light. The photodiode 202 located directly under the second lower PIN diode 12b and the second upper PIN diode 16b may receive or absorb green light. The photodiode 202 located directly under the third lower PIN diode 12c and the third upper PIN diode 16c may receive or absorb red light. Accordingly, the PIN diodes 12a, 12b, 12c of the lower structure 10A may be configured to filter the light. The PIN diodes 16a, 16b, 16c of the upper structure 10B may be configured to filter the light. The PIN diodes 12a, 12b, 12c of the lower structure 10A and the PIN diodes 16a, 16b, 16c of the upper structure 10B may be configured to filter the light and may optimize light absorption and performance. In some embodiments, the upper structure 10B may be omitted.

The sizes of the lower structure 10A and the upper structure 10B could be minimized since color filters are replaced by the PIN diodes 16a, 16b, 16c of the upper structure 10B and the PIN diodes 12a, 12b, 12c. In addition, the quantum efficiency of the semiconductor device 1 is improved.

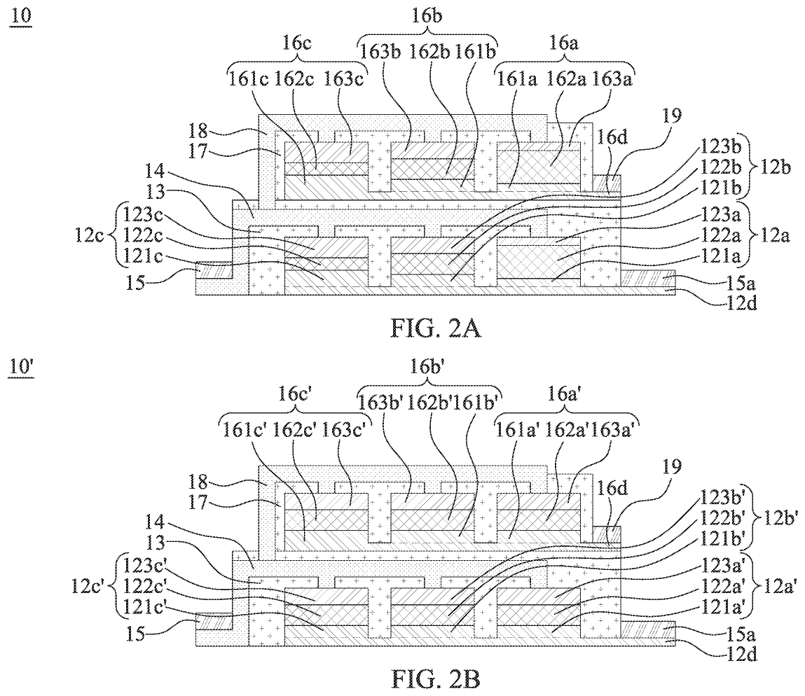

FIG. 2A is a cross-sectional view of the first substrate 10 of FIG. 1.

The first lower PIN diode 12a and the first upper PIN diode 16a may be configured to allow transmission of light with wavelength from 450 nm to 495 nm. The first lower PIN diode 12a absorbs green light and the first upper PIN diode 16a absorbs red light so a combination of the first lower PIN diode 12a and the first upper PIN diode 16a allows transmission of blue light. The second lower PIN diode 12b and the second upper PIN diode 16b may be configured to allow transmission of light with wavelength from 495 nm to 570 nm. The second lower PIN diode 12b absorbs blue light and the second upper PIN diode 16b absorbs red light so a combination of the second lower PIN diode 12b and the second upper PIN diode 16b allow transmission of green light. The second lower PIN diode 12c and the third upper PIN diode 16c may be configured to allow transmission of light with wavelength from 620 nm to 750 nm. The third lower PIN diode 12c absorbs blue light and the third upper PIN diode 16c absorbs green light so a combination of the first lower PIN diode 12c and the third upper PIN diode 16c allow transmission of red light.

Regarding the first lower PIN diode 12a, a thickness of the intrinsic Si layer 122a may be greater than a thickness of the p-doped Si layer 121a. The thickness of the p-doped Si layer 121a may be greater than or equal to a thickness of the n-doped Si layer 123a.

Regarding the second lower PIN diode 12b, a thickness of the intrinsic Si layer 122b may be greater than or equal to a thickness of the p-doped Si layer 121b. A thickness of the n-doped Si layer 123b may be greater than or equal to the thickness of the p-doped Si layer 121b.

Regarding the third lower PIN diode 12c, a thickness of the n-doped Si layer 123c may be greater than or equal to a thickness of the p-doped Si layer 121c. The thickness of the p-doped Si layer 121c may be greater than a thickness of the intrinsic Si layer 122c.

In some embodiments, the thickness of the p-doped Si layer 121a, 121b, or 121c may have a range from 40 nm to 80 nm. The thickness of the intrinsic Si layer 122a, 122b, or 122c may have a range from 30 nm to 80 nm. The thickness of the n-doped Si layer 123a, 123b, or 123c may have a range from 10 nm to 50 nm. Each thickness of the PIN diodes 12a, 12b, 12c may be from 200 nm to 250 nm.

In some embodiments, the thickness of the p-doped Si layer 121a, 121b, or 121c, the thickness of the intrinsic Si layer 122a, 122b, or 122c, and the thickness of the n-doped Si layer 123a, 123b, or 123c may be adjusted to change the absorption of the PIN diodes 12a, 12b, 12c. The thicknesses of the PIN diodes 12a, 12b, 12c may be the same as the thicknesses of the PIN diodes 16a, 16b, 16c. In some embodiments, the thicknesses of the PIN diodes 12a, 12b, 12c may be different from the thicknesses of the PIN diodes 16a, 16b, 16c. Each PIN diode may be adjusted to absorb desired wavelength of light based on need. Accordingly, different combinations of the PIN diodes 12a, 12b, 12c, and the PIN diodes 16a, 16b, 16c may be designed to absorb different wavelengths of light based on a desired layout.

FIG. 2B is a cross-section view of a first substrate 10′, in accordance with some embodiments of the present disclosure. The structure of the first substrate 10′ is similar to the structure of the first substrate 10 of FIG. 2A, except that the thicknesses of the p-doped Si layer, the intrinsic Si layer, and the n-doped Si layer are the same. The first substrate 10′ includes PIN diodes 12a′, 12b′, 12c′ and PIN diodes 16a′, 16b′, 16c′. Each PIN diode has respective p-doped Si layer, intrinsic Si layer, and n-doped Si layer. Each PIN diode may be configured to receive or absorb different wavelengths of light by adjusting doping concentrations of respective p-doped Si layer and n-doped Si layer.

In some embodiments, a doping concentration of the p-doped Si layer 121a′, 121b′, or 121c′ may have a range from 1310¹⁷ cm⁻³ to 1310²⁰ cm⁻³. A doping concentration of the n-doped Si layer 123a′, 123b′, or 123c′ may have a range from 1310¹⁷ cm⁻³ to 1310¹⁸ cm⁻³.

Similarly, a doping concentration of the p-doped Si layer 161a′, 161b′, or 161c′ may have a range from 1310¹⁷ cm⁻³ to 1310²⁰ cm⁻³. A doping concentration of the n-doped Si layer 163a′, 163b′, or 163c′ may have a range from 1310¹⁷ cm⁻³ to 1310¹⁸ cm⁻³.

In some embodiments, the doping concentrations of the PIN diodes 12a′, 12b′, 12c′ may be different from the doping concentrations of the PIN diodes 16a′, 16b′, 16c′. Each PIN diode may be adjusted to absorb desired wavelength of light based on need. Accordingly, different combinations of the PIN diodes 12a′, 12b′, 12c′ with different doping concentrations, and the PIN diodes 16a′, 16b′, 16c′ with different doping concentrations may be designed to absorb different wavelengths of light based on a desired layout.

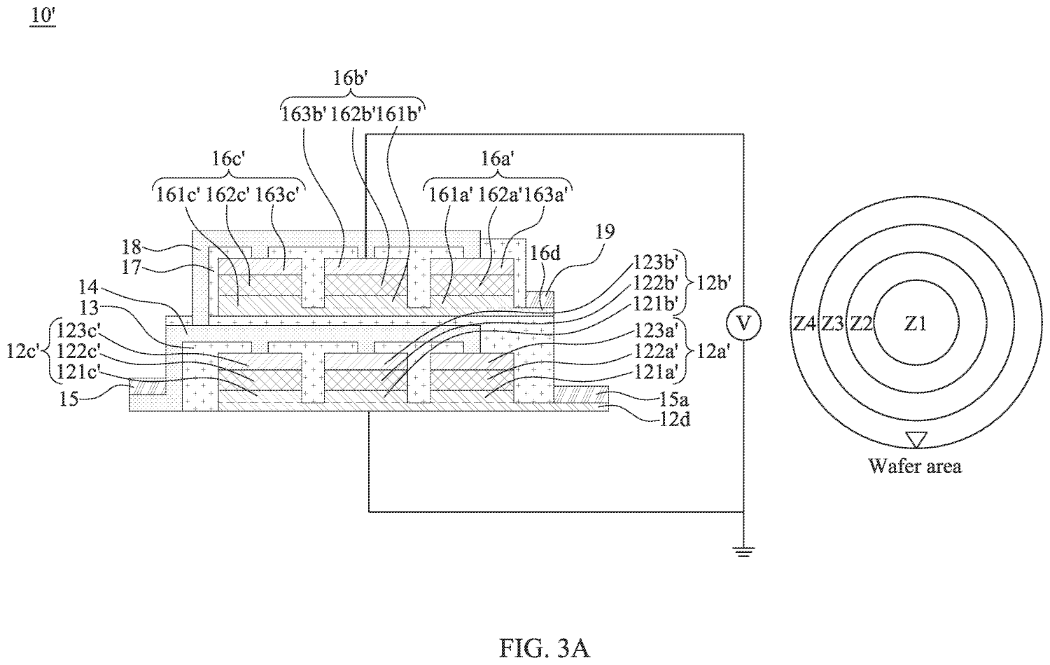

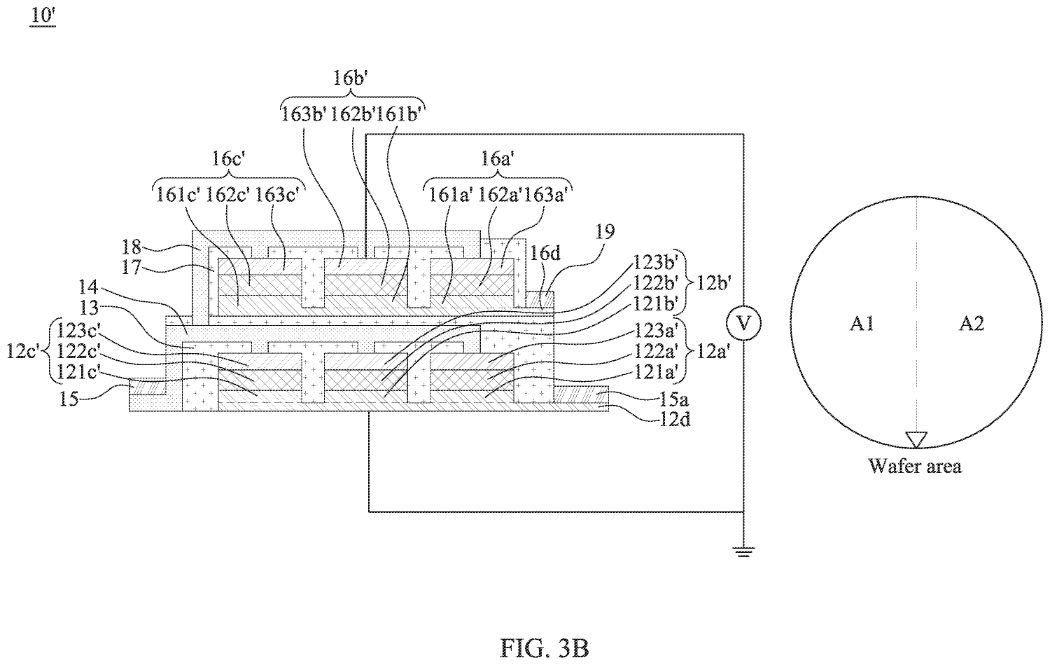

FIG. 3A is a cross-sectional view of the first substrate 10′ applied with different voltages, in accordance with some embodiments of the present disclosure. The first substrate 10′ includes PIN diodes 12a′, 12b′, 12c′ and PIN diodes 16a′, 16b′, 16c′. Each PIN diode has respective p-doped Si layer, intrinsic Si layer, and n-doped Si layer. Each PIN diode may be configured to receive or absorb different wavelengths of light by applying different input voltage biases.

A voltage bias may be applied to the p-doped layer 12d and second conductive layer 18. In some embodiments, the voltage bias may be applied to the conductive pads 15 and 19 to control the PIN diodes 12a′, 12b′, 12c′ and the PIN diodes 16a′, 16b′, 16c′. In accordance with different voltages, the PIN diodes 12a′, 12b′, 12c′ and the PIN diodes 16a′, 16b′, 16c′ may be configured to receive or absorb different wavelengths of light.

In some embodiments, wafer areas Z1, Z2, Z3, and Z4 may be applied with different voltage biases. In the wafer area Z1, a first voltage bias has a range from 0.37V to 0.39V. The PIN diodes in the wafer area Z1 may be configured to allow transmission of light with wavelength from 430 nm to 470 nm. In the wafer area Z2, a second voltage bias has a range from 0.41V to 0.43V. The PIN diodes in the wafer area Z2 may be configured to allow transmission of light with wavelength from 480 nm to 520 nm. In the wafer area Z3, a third voltage bias has a range from 0.45V to 0.47V. The PIN diodes in the wafer area Z3 may be configured to allow transmission of light with wavelength from 580 nm to 620 nm. In the wafer area Z4, a fourth voltage bias has a range from 0.49V to 0.51V. The PIN diodes in the wafer area Z4 may be configured to allow transmission of light with wavelength from 640 nm to 680 nm.

In some embodiments, the voltage bias of each of the wafer areas Z1, Z2, Z3, and Z4 may be changed based on need, such that the PIN diodes in the respective wafer areas Z1, Z2, Z3, and Z4 may be configured to allow transmission of light with desired wavelengths of light.

FIG. 3B is a cross-section view of the first substrate 10′ applied with different voltages, in accordance with some embodiments of the present disclosure. The first substrate 10′ includes PIN diodes 12a′, 12b′, 12c′ and PIN diodes 16a′, 16b′, 16c′. Each PIN diode has respective p-doped Si layer, intrinsic Si layer, and n-doped Si layer. Each PIN diode may be configured to receive or absorb different wavelengths of light by applying different input voltage biases.

Similarly, a voltage bias may be applied to the p-doped layer 12d and second conductive layer 18. In some embodiments, the voltage bias may be applied to the conductive pads 15 and 19 to control the PIN diodes 12a′, 12b′, 12c′ and the PIN diodes 16a′, 16b′, 16c′. In accordance with different voltages, the PIN diodes 12a′, 12b′, 12c′ and the PIN diodes 16a′, 16b′, 16c′ may be configured to receive or absorb different wavelengths of light.

In some embodiments, wafer areas A1 and A2 may be applied with different voltage biases. In the wafer area A1, a first voltage bias has a range from 0.2V to 0.5V. The PIN diodes in the wafer area A1 may be configured to allow transmission of light with wavelength from 380 nm to 780 nm. In the wafer area A2, a second voltage bias greater than 0.52V. The PIN diodes in the wafer area A2 may be configured to allow transmission of light with wavelength greater than 780 nm. In some embodiments, an input voltage bias may be modified to make the PIN diodes absorb different wavelengths of light.

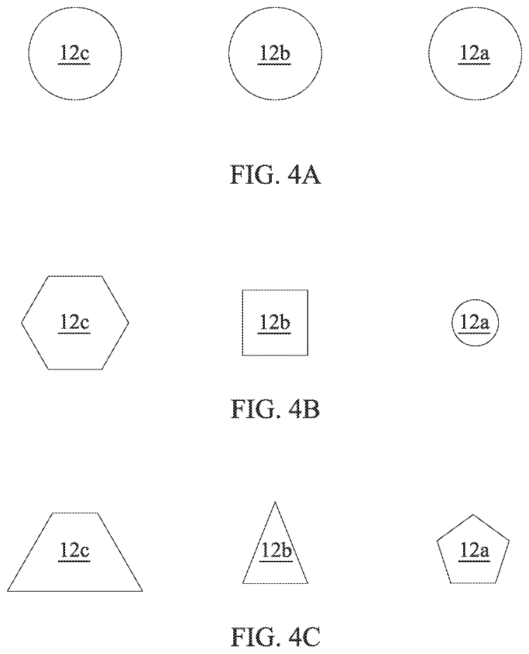

FIG. 4A is a top view of patterns of PIN diodes 12a, 12b, 12c of a semiconductor device 1, in accordance with some embodiments of the present disclosure.

The patterns of the PIN diodes 12a, 12b, 12c of the semiconductor device 1 are the same. The patterns of the PIN diodes 12a, 12b, 12c may include a shape designed as circle. In some embodiments, the shapes of the PIN diodes 12a, 12b, 12c may be designed as other shapes, such as triangle, square, rectangle, trapezoid, pentagon, or hexagon.

In some embodiments, patterns of the PIN diodes 16a, 16b, 16c of the semiconductor device 10 may be designed the same as the patterns of the PIN diodes 12a, 12b, 12c.

FIG. 4B is a top view of patterns of PIN diodes 12a, 12b, 12c of a semiconductor device 1, in accordance with some embodiments of the present disclosure.

The patterns of the PIN diodes 12a, 12b, 12c of the semiconductor device 1 are different. The pattern of the first lower PIN diode 12a include a shape designed as circle. The pattern of the second lower PIN diode 12b include a shape designed as square. The pattern of the third lower PIN diode 12c include a shape designed as hexagon. In some embodiments, the first lower PIN diode 12a is configured to allow transmission of blue light. The second lower PIN diode 12b is configured to allow transmission of green light. The third lower PIN diode 12c is configured to allow transmission of red light. A size of the pattern of the third lower PIN diode 12c is greater than a size of the pattern of the second lower PIN diode 12b. A size of the pattern of the second lower PIN diode 12b is greater than a size of the pattern of the third lower PIN diode 12c. Accordingly, red light with low energy would easily pass through the third lower PIN diode 12c. Blue light with high energy would normally pass through the first lower PIN diode 12a. In some embodiments, the shapes of the patterns of the PIN diodes 12a, 12b, 12c may be changed but the size of the pattern of the third lower PIN diode 12c is still the largest one and the size of the pattern of the first lower PIN diode 12a is still the smallest one.

FIG. 4C is a top view of patterns of PIN diodes 12a, 12b, 12c of a semiconductor device 1, in accordance with some embodiments of the present disclosure.

The pattern of the first lower PIN diode 12a include a shape designed as trapezoid. The pattern of the second lower PIN diode 12b include a shape designed as triangle. The pattern of the third lower PIN diode 12c include a shape designed as pentagon.

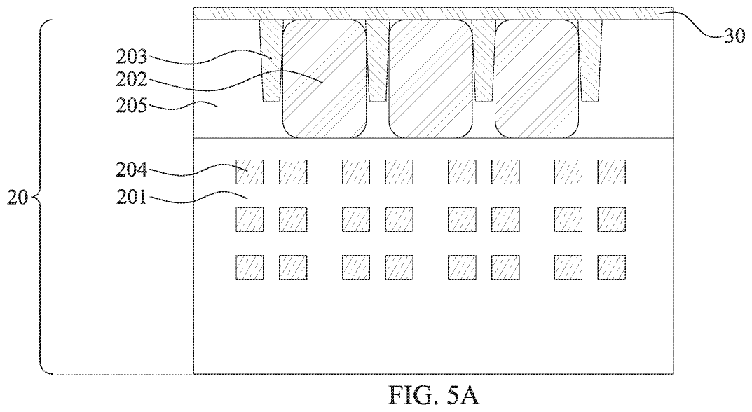

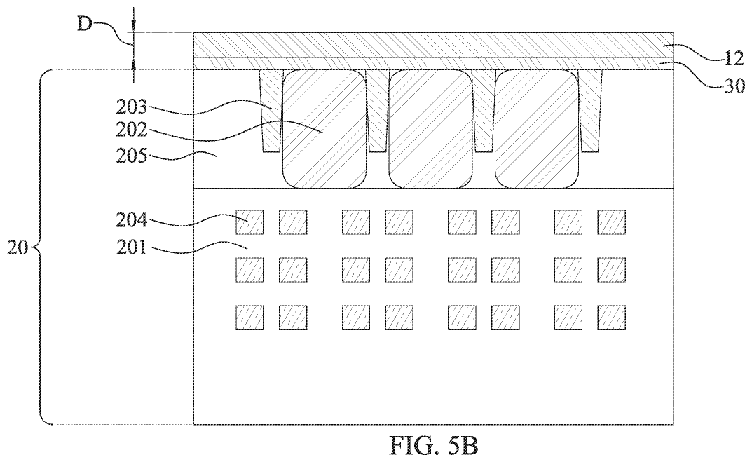

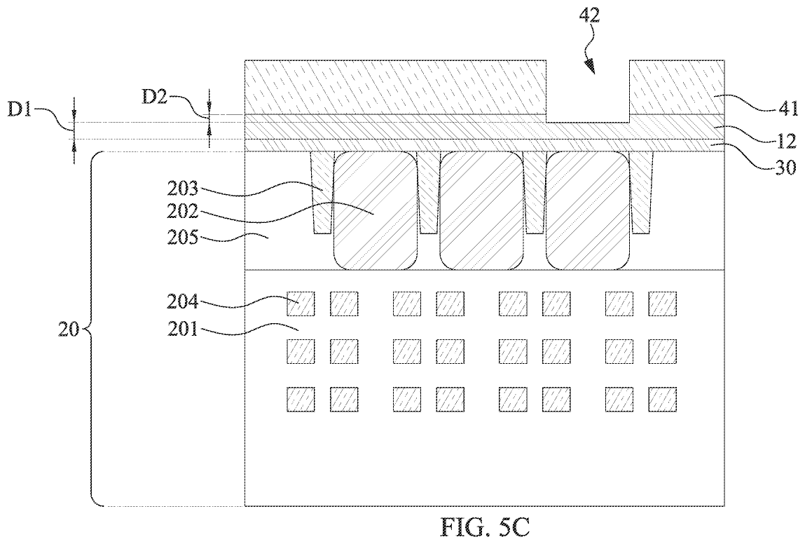

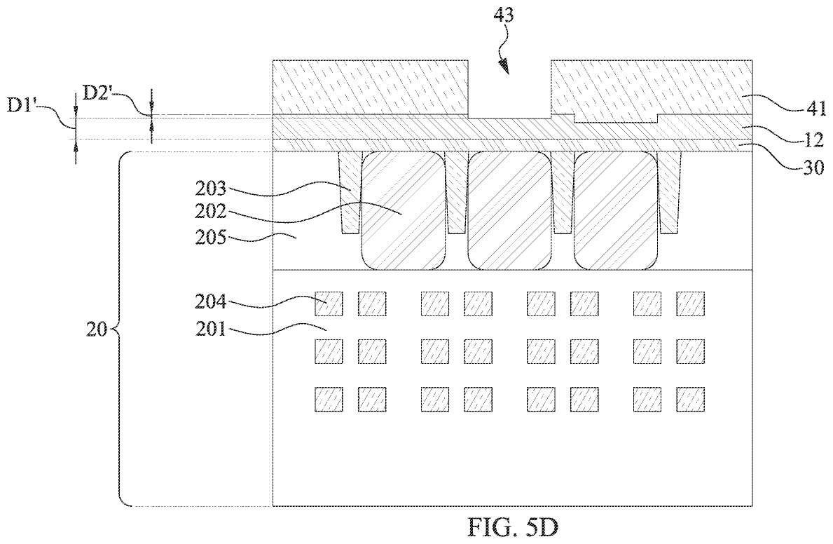

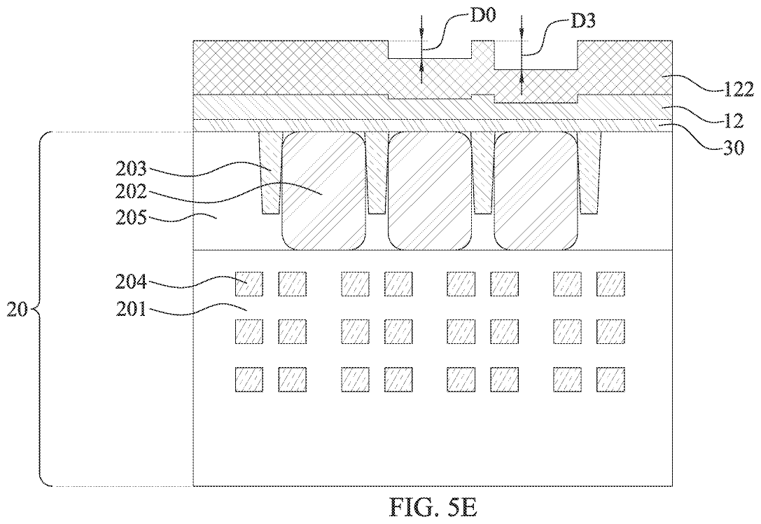

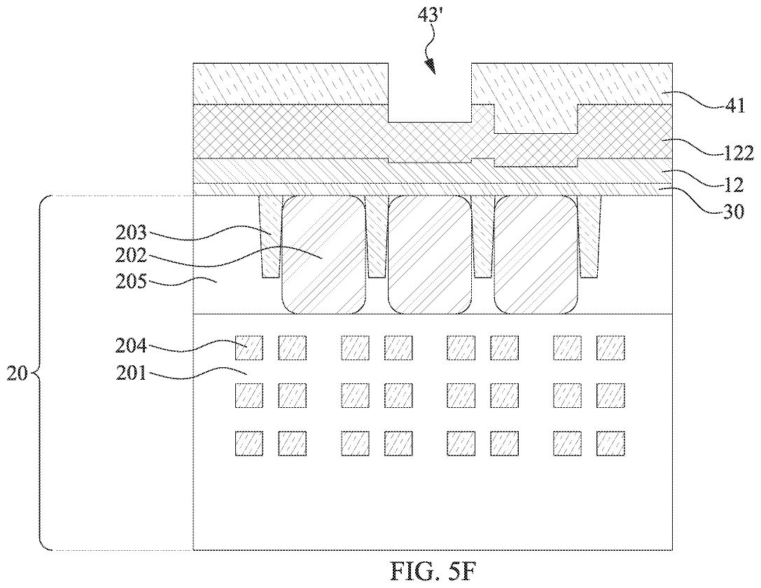

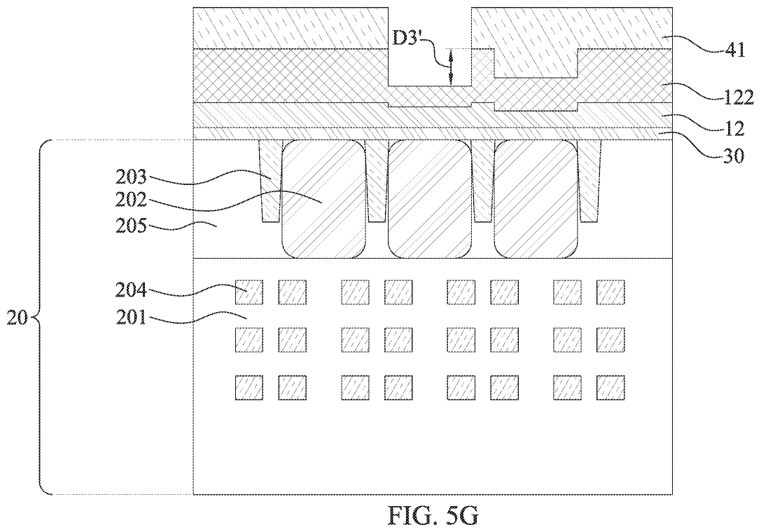

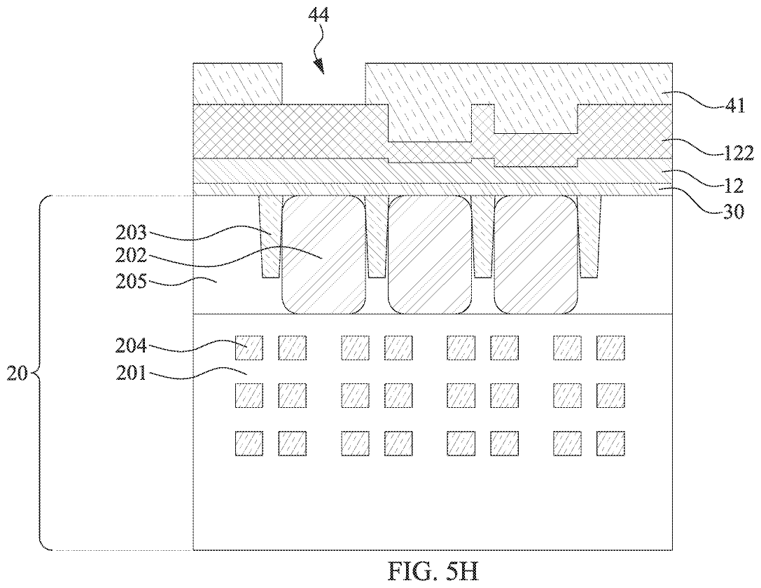

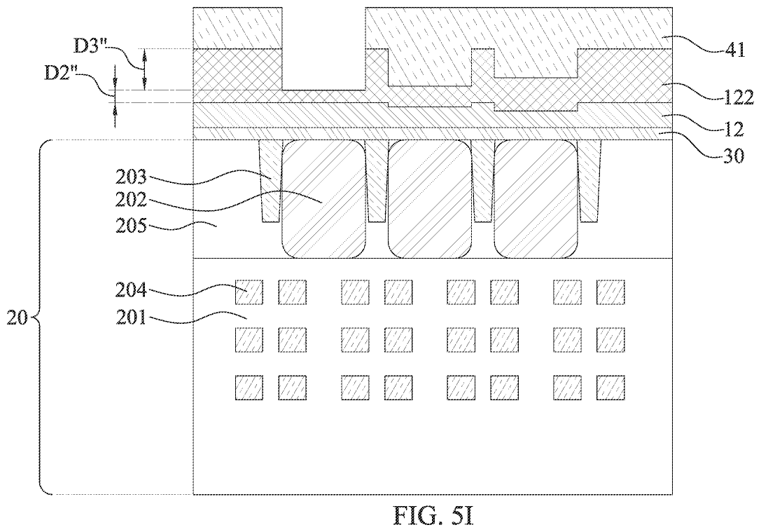

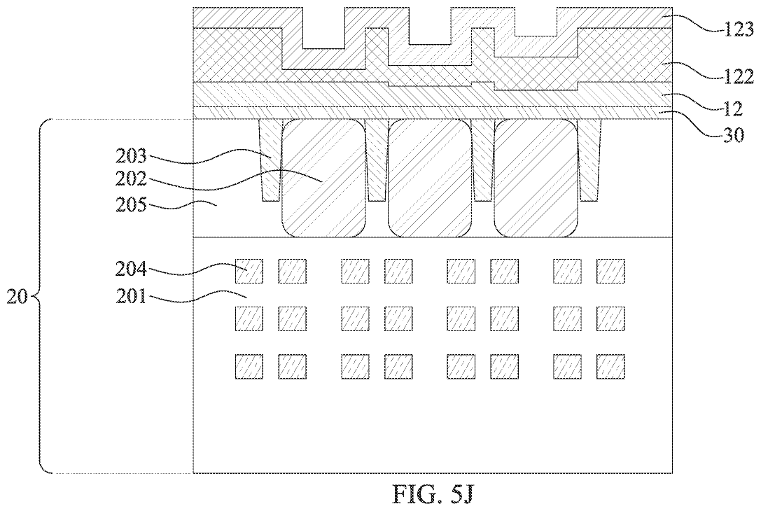

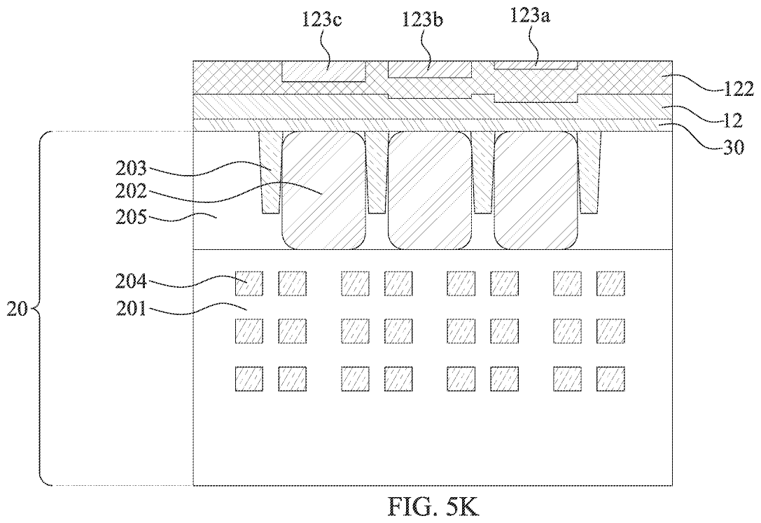

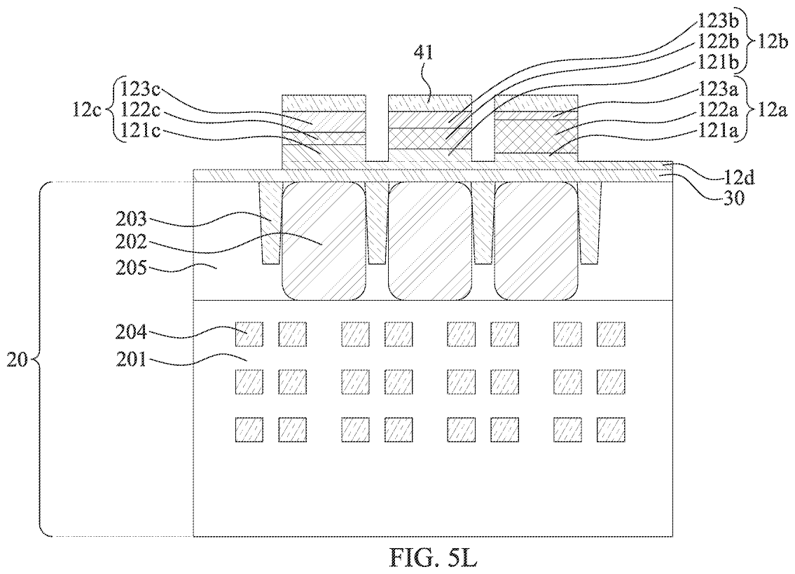

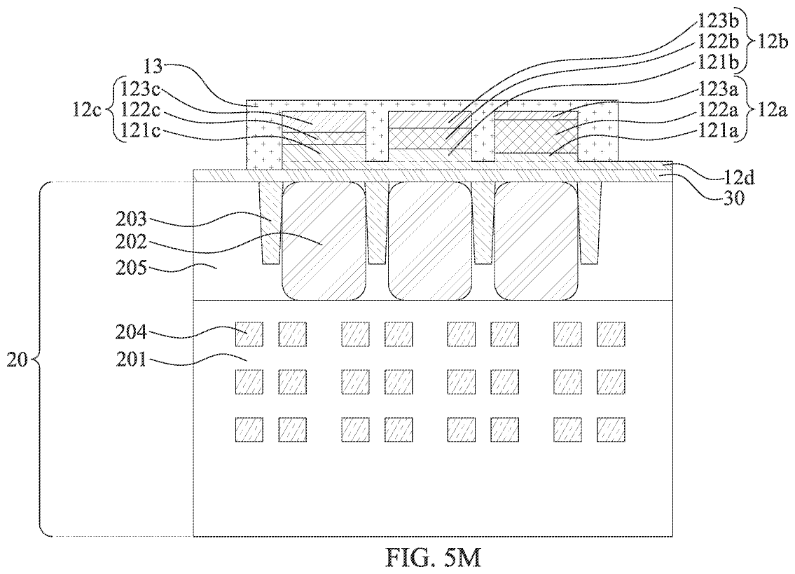

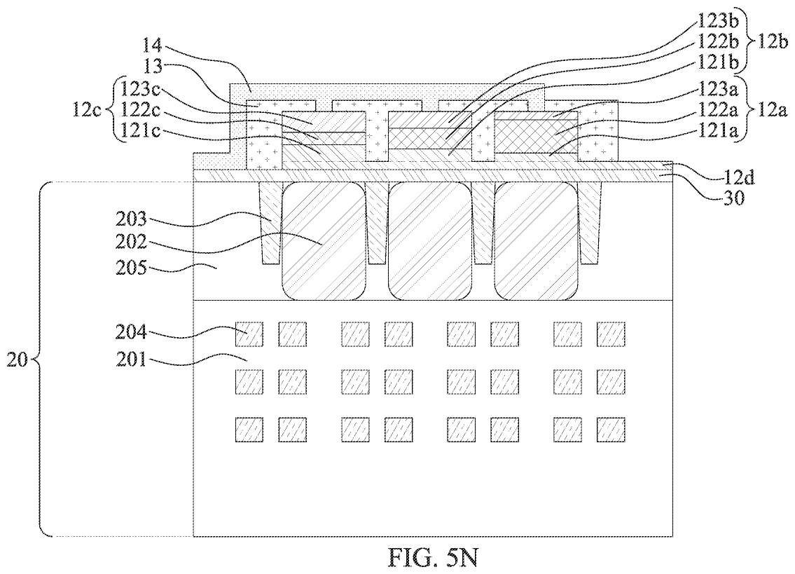

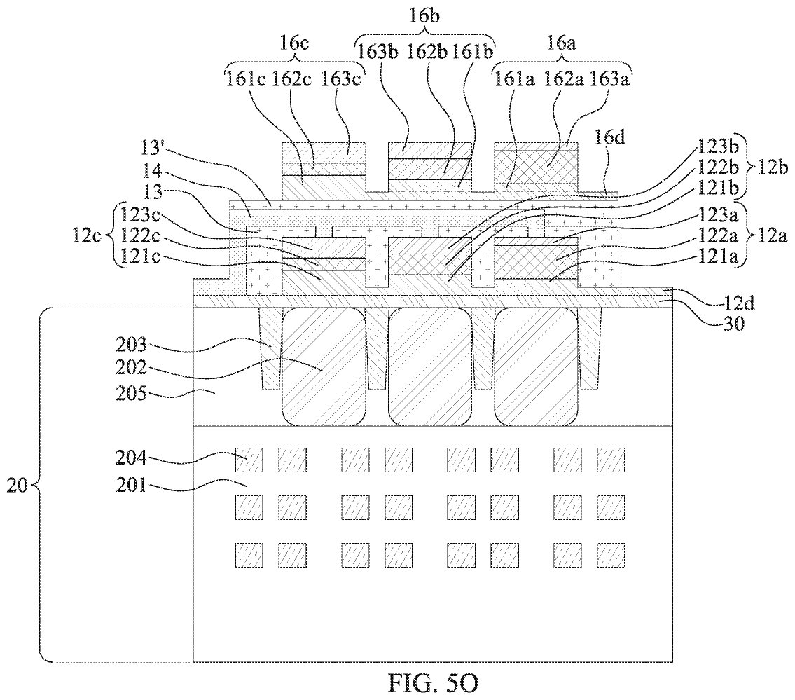

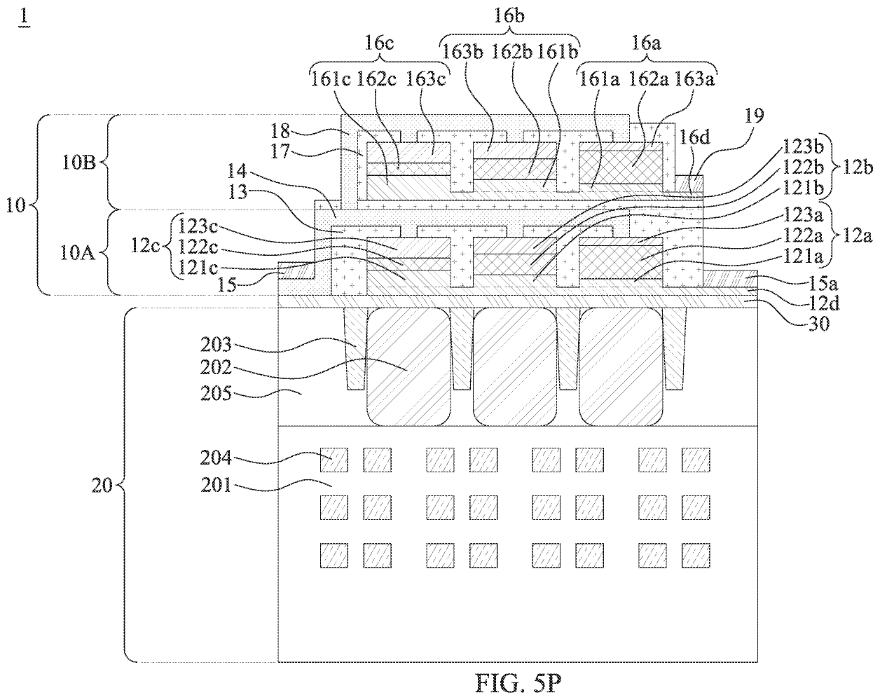

FIG. 5A to FIG. 5P illustrates a method of manufacturing a semiconductor device 1 according to some embodiments of the present disclosure.

Referring to FIG. 5A, the method for manufacturing the semiconductor device 1 includes providing a substrate 20. The substrate 20 includes a substrate region 201, a plurality of photodiodes 202, a plurality of isolation structures 203, a plurality of metal layers 204, and a doped region 205. The substrate 20 may be a semiconductor device. The substrate 20 may be a semiconductor substrate (e.g., a wafer). The semiconductor substrate 20 may be a silicon substrate. The substrate 20 may be pre-formed by a plurality of operations.

The substrate region 201 may be a silicon carrier. The material of the substrate region 201 may include intrinsic silicon (Si). The plurality of metal layers 204 are disposed within the substrate region 201.

The doped region 205 is formed on the substrate region 201. The doped region 205 may be a p-doped silicon region. The plurality of photodiodes 202 and the plurality of isolation structures 203 are formed within the doped region 205. In some embodiments, the plurality of isolation structures 203 are STI structures. The STI structures 203 may reduce the optical or electrical cross-talk between the neighboring photodiodes 202.

Two adjacent isolation structures 203 may define an active region. One photodiode 202 may be disposed between the active region defined by the two adjacent isolation structures 203. The photodiodes 202 are separated from one another by the isolation structures 203. The photodiode 202 stores photogenerated charges.

A passivation layer 30 is formed on the doped region 205 and covers the plurality of photodiodes 202 and the plurality of isolation structures 203. The passivation layer 30 may be formed by HDP chemical vapor deposition, a plasma-enhanced chemical vapor deposition (PECVD) process and/or other suitable deposition or oxidation processes. The passivation layer 30 is in contact with a light exposure area of each photodiode 202.

Referring to FIG. 5B, a p-doped Si layer 12 may be epitaxially grown on the passivation layer 30. A doping concentration of the p-doped Si layer 12 may be adjusted during the growing operation. The p-doped Si layer 12 has a thickness D.

Referring to FIG. 5C, a photoresist 41 is applied on the p-doped Si layer 12 for a first etching operation. An opening 42 is defined in the photoresist 41. The opening 42 aligns the right one of the photodiodes 202. Subsequently, the first etching operation is performed on the p-doped Si layer 12 to form a first recess with a depth D2. The exposed portion of the p-doped Si layer 12 has a thickness D1. After the first etching operation is completed, the photoresist 41 is removed.

Referring to FIG. 5D, a photoresist 41 is applied on the p-doped Si layer 12 for a second etching operation. An opening 43 is defined in the photoresist 41. The opening 43 aligns the central one of the photodiodes 202. Subsequently, the second etching operation is performed on the p-doped Si layer 12 to form a second recess with a depth D2′. The exposed portion of the p-doped Si layer 12 has a thickness D1′. After the second etching operation is completed, the photoresist 41 is removed.

Referring to FIG. 5E, an intrinsic silicon layer 122 is epitaxially grown on the p-doped Si layer 12. The intrinsic silicon layer 122 is conformally grown on the p-doped Si layer 12. The intrinsic silicon layer 122 has first and second recesses corresponding to the first and second recesses of the p-doped Si layer 12. The first recess of the intrinsic silicon layer 122 has a depth D3. The second recess of the intrinsic silicon layer 122 has a depth DO.

Referring to FIG. 5F, a photoresist 41 is applied on the intrinsic silicon layer 122 for a third etching operation. An opening 43′ is defined in the photoresist 41. The opening 43 aligns the central one of the photodiodes 202.

Referring to FIG. 5G, the third etching operation is performed on the intrinsic silicon layer 122 to further etch the second recess, such that the depth of the second recess changes from the depth DO to D3′. After the third etching operation is completed, the photoresist 41 is removed.

Referring to FIG. 5H, a photoresist 41 is applied on the intrinsic silicon layer 122 for a fourth etching operation. An opening 44 is defined in the photoresist 41. The opening 44 aligns the left one of the photodiodes 202.

Referring to FIG. 5I, the fourth etching operation is performed on the intrinsic silicon layer 122 to form a third recess with a depth D3″. The exposed portion of the intrinsic silicon layer 122 has a thickness D2″. After the fourth etching operation is completed, the photoresist 41 is removed.

Referring to FIG. 5J, an n-doped Si layer 123 is epitaxially grown on the intrinsic silicon layer 122. The n-doped Si layer 123 is conformally grown on the intrinsic silicon layer 122. The n-doped Si layer 123 has first, second, and third recesses corresponding to the first, second, and third recesses of the intrinsic silicon layer 122. The first, second, and third recesses of the n-doped Si layer 123 have respective depths.

Referring to FIG. 5K, a planarization operation is performed to form the n-doped Si layers 123a, 123b, 123c. The planarization operation may be a chemical-mechanical polishing (CMP).

Referring to FIG. 5L, a photoresist 41 is applied on the intrinsic silicon layer 122 for a fifth etching operation. The photoresist 41 is patterned to have three patterns on the n-doped Si layers 123a, 123b, 123c. The fifth etching operation is performed to form PIN diodes 12a, 12b, 12c and a p-doped layer 12d. After the fifth etching operation is completed, the photoresist 41 is removed.

The first lower PIN diode 12a includes a p-doped Si layer 121a, an intrinsic Si layer 122a, and an n-doped Si layer 123a. The second lower PIN diode 12b includes a p-doped Si layer 121b, an intrinsic Si layer 122b, and an n-doped Si layer 123b. The third lower PIN diode 12c comprises a p-doped Si layer 121c, an intrinsic Si layer 122c, and an n-doped Si layer 123c. According to the above etching operations, desired thicknesses of the respective layers of the PIN diodes 12a, 12b, 12c can be adjusted.

According to the above operations, it can be known that the p-doped Si layer 121a, the p-doped Si layer 121b, the p-doped Si layer 121c, and the p-doped layer 12d are formed from one layer (i.e., p-doped layer 12). The p-doped Si layer 121a, the p-doped Si layer 121b, the p-doped Si layer 121c, and the p-doped layer 12d are integrally formed. The p-doped Si layer 121a, the p-doped Si layer 121b, the p-doped Si layer 121c, and the p-doped layer 12d may be formed as one layer.

Referring to FIG. 5M, a first dielectric layer 13 is formed on the passivation layer 30 and covers the PIN diodes 12a, 12b, 12c. The first dielectric layer 13 partially covers the p-doped layer 12d. The first dielectric layer 13 may be formed by HDP chemical vapor deposition, a plasma-enhanced chemical vapor deposition (PECVD) process and/or other suitable deposition or oxidation processes.

Referring to FIG. 5N, a first conductive layer 14 is formed on the first dielectric layer 13 by a patterning operation. The first conductive layer 14 is in contact with the respective n-doped layers of the PIN diodes 12a, 12b, 12c. In some embodiments, the first conductive layer 14 may be formed by ALD, CVD, PVD (such as sputtering) or any other suitable methods. The patterned operation may include a lithographic operation and an etching operation. The etching operation may be wet etching or dry etching.

The first conductive layer 14 may be a transparent conductive layer. In some embodiments, the first conductive layer 14 may include an indium-containing or gallium-containing metal oxide semiconductor material (e.g., indium-gallium-zinc oxide (IGZO), indium-zinc oxide (IZO), indium-tin oxide (ITO) or indium tungsten oxide (IWO)), or a zinc-containing metal oxide semiconductor material (e.g., zinc oxide (ZnO), gallium-zinc oxide (GZO), zinc-tin oxide (ZTO) or combinations thereof).

Referring to FIG. 5O, a first dielectric layer 13′ is formed on the first dielectric layer 13 and the first conductive layer 14. Once the formation of the first dielectric layer 13′ is completed, there would be no boundary between the first dielectric layer 13 and the first dielectric layer 13′. In some embodiments, the first dielectric layer 13 and the first dielectric layer 13′ may be deemed as one dielectric layer.

PIN diodes 16a, 16b, 16c, and p-doped layer 16d may be similarly formed on the first dielectric layer 13′ according to the operations of FIGS. 5C-5L.

Referring to FIG. 5P, a second dielectric layer 17 is formed on the PIN diodes 16a, 16b, 16c. Once the formation of the second dielectric layer 17 is completed, there would be no boundary between the first dielectric layer 13 and the second dielectric layer 17. In some embodiments, the first dielectric layer 13 and the second dielectric layer 17 may be deemed as one dielectric layer.

Subsequently, a second conductive layer 18 is formed on the dielectric layer 18 by a patterning operation. The second conductive layer 18 is in contact with the respective n-doped layers of the PIN diodes 16a, 16b, 16c. The formation of the second conductive layer 18 may be similar to the formation of the first conductive layer 14.

After the formation of the second conductive layer 18, conductive pads 15 and 19 are formed on the p-doped layer 12d, the first conductive layer 14, and the p-doped layer 16d so as to form the semiconductor device 10. Accordingly, the semiconductor device 1 is completed.

Some embodiments of the present disclosure provide a semiconductor device. The semiconductor device comprises a substrate and a wafer disposed on the substrate. The wafer includes a p-doped layer disposed on the substrate; a first diode disposed on the p-doped layer; a second diode disposed on the p-doped layer; a third diode disposed on the p-doped layer; and a dielectric layer disposed on the substrate and covering the first, second, and third diodes. The first, second, and third diodes are disposed side by side.

Some embodiments of the present disclosure provide a semiconductor device. The semiconductor device comprises a first wafer, a passivation layer disposed on the first wafer, and a second wafer disposed on the passivation layer. The second wafer includes a plurality of first diodes disposed in parallel; a first dielectric layer disposed on the passivation layer and covering the plurality of first diodes; a first transparent conductive layer disposed on the first dielectric layer; a second dielectric layer disposed on the first dielectric layer; a plurality of second diodes disposed in parallel and covered by the second dielectric layer; and a second transparent conductive layer disposed on the second dielectric layer. Each of the plurality of second diodes corresponds to a respective diode of the plurality of first diodes.

Some embodiments of the present disclosure provide a method for manufacturing a semiconductor device. The method comprises providing a substrate; forming a plurality of first diodes on the substrate, the plurality of first diodes being disposed in parallel; forming a first dielectric layer on the substrate to cover the plurality of first diodes; and forming a first transparent conductive layer on the first dielectric layer.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate; and
a wafer disposed on the substrate, and comprising:
a p-doped layer disposed on the substrate;
a first diode disposed on the p-doped layer;
a second diode disposed on the p-doped layer;
a third diode disposed on the p-doped layer; and
a dielectric layer disposed on the substrate and covering the first, second, and third diodes,
wherein the first, second, and third diodes are disposed side by side.

2. The semiconductor device of claim 1, wherein the first diode comprises a p-doped silicon layer, an intrinsic silicon layer disposed on the p-doped silicon layer, and an n-doped silicon layer disposed on the intrinsic silicon layer; the second diode comprises a p-doped silicon layer, an intrinsic silicon layer disposed on the p-doped silicon layer, and an n-doped silicon layer disposed on the intrinsic silicon layer; and the third diode comprises a p-doped silicon layer, an intrinsic silicon layer disposed on the p-doped silicon layer, and an n-doped silicon layer disposed on the intrinsic silicon layer.

3. The semiconductor device of claim 2, wherein a thickness of the p-doped silicon layer of the first diode, a thickness of the intrinsic silicon layer of the first diode, and a thickness of the n-doped silicon layer of the first diode are different from one another.

4. The semiconductor device of claim 3, wherein the thickness of the p-doped silicon layer of the first diode is less than the thickness of the intrinsic silicon layer of the first diode, and the thickness of the intrinsic silicon layer of the first diode is greater than the thickness of the n-doped silicon layer of the first diode.

5. The semiconductor device of claim 2, wherein a thickness of the p-doped silicon layer of the first diode, a thickness of the intrinsic silicon layer of the first diode, and a thickness of the n-doped silicon layer of the first diode are identical to one another.

6. The semiconductor device of claim 3, wherein the thickness of the p-doped silicon layer of the second diode is greater than a thickness of the p-doped silicon layer of the first diode, the thickness of the intrinsic silicon layer of the second diode is less than a thickness of the intrinsic silicon layer of the first diode, and the thickness of the n-doped silicon layer of the second diode is greater than a thickness of the n-doped silicon layer of the first diode.

7. The semiconductor device of claim 6, wherein the thickness of the p-doped silicon layer of the second diode is less than a thickness of the p-doped silicon layer of the third diode, the thickness of the intrinsic silicon layer of the second diode is greater than a thickness of the intrinsic silicon layer of the third diode, and the thickness of the n-doped silicon layer of the second diode is less than a thickness of the n-doped silicon layer of the third diode.

8. A semiconductor device, comprising:
a first wafer;
a passivation layer disposed on the first wafer; and
a second wafer disposed on the passivation layer, and comprising:
a plurality of lower diodes disposed side by side;
a first dielectric layer disposed on the passivation layer and covering the plurality of lower diodes;
a first transparent conductive layer disposed on the first dielectric layer;
a second dielectric layer disposed on the first dielectric layer;
a plurality of upper diodes disposed side by side and covered by the second dielectric layer;
a second transparent conductive layer disposed on the second dielectric layer,
wherein each of the plurality of upper diodes corresponds to a respective one of the plurality of lower diodes.

9. The semiconductor device of claim 8, wherein a first diode of the plurality of lower diodes and a first diode of the plurality of upper diodes are configured to allow transmission of light with a wavelength from 620 nm to 750 nm.

10. The semiconductor device of claim 8, wherein a second diode of the plurality of lower diodes and a second diode of the plurality of upper diodes are configured to allow transmission of light with a wavelength from 495 nm to 570 nm.

11. The semiconductor device of claim 8, wherein a second diode of the plurality of lower diodes and a second diode of the plurality of upper diodes are configured to allow transmission of light with a wavelength from 450 nm to 495 nm.

12. The semiconductor device of claim 8, wherein the second wafer further comprises a first p-doped layer disposed under the plurality of lower diodes, and wherein the first p-doped layer and a plurality of p-doped silicon layers of the plurality of lower diodes are integrally formed.

13. The semiconductor device of claim 8, wherein the first transparent conductive layer is electrically connected to the second transparent conductive layer.

14. The semiconductor device of claim 13, wherein the first transparent conductive layer is electrically connected to the plurality of lower diodes and the second transparent conductive layer is electrically connected to the plurality of upper diodes.

15. The semiconductor device of claim 14, wherein the second wafer further comprises a first conductive pad disposed on the first transparent conductive layer, wherein the first conductive pad is configured to be a cathode.

16. The semiconductor device of claim 15, wherein the second wafer further comprises a second conductive pad disposed on the first p-doped layer, wherein the second conductive pad is configured to be an anode.

17. The semiconductor device of claim 16, wherein a negative voltage is applied to the first conductive pad and a positive voltage is applied to the second conductive pad to control the plurality of lower diodes.

18. A method for manufacturing a semiconductor device, comprising:
providing a substrate;
forming a plurality of lower diodes on the substrate, the plurality of lower diodes being disposed side by side;
forming a first dielectric layer on the substrate to cover the plurality of lower diodes; and
forming a first transparent conductive layer on the first dielectric layer.

19. The method of claim 18, further comprising:
forming a second dielectric layer on the first dielectric layer;
forming a plurality of upper diodes on the second dielectric layer, the plurality of upper diodes being disposed side by side;
forming a third dielectric layer on the second dielectric layer to cover the plurality of upper diodes; and
forming a second transparent conductive layer on the third dielectric layer.

20. The method of claim 18, wherein the substrate comprises a plurality of photodiodes, and wherein each of the plurality of photodiodes corresponds to a respective one of the plurality of lower diodes.
